(19) United States
(12) Patent Application Publication
(10) Pub. No.: US 2018/0186133 A1
(43) Pub. Date: Jul. 5, 2018

(54) ADHESIVE COMPOSITION AND FLEXIBLE LAMINATE

(71) Applicant: TAIFLEX Scientific Co., Ltd., KAOHSIUNG (TW)

(72) Inventors: Hsiu-Chu Wu, KAOHSIUNG (TW); Meng-Cheng Tsai, KAOHSIUNG (TW); Chung-Hsiao Lai, KAOHSIUNG (TW)

(73) Assignee: TAIFLEX Scientific Co., Ltd., KAOHSIUNG (TW)

(21) Appl. No.: 15/448,597

(22) Filed: Mar. 3, 2017

(30) Foreign Application Priority Data
Jan. 3, 2017 (TW) 106100084

(51) Int. Cl. B32B 27/28; C09J 183/00; H05K 1/03

(52) U.S. Cl. CPC B32B 27/28; H05K 1/0393; C09J 183/00

(57) ABSTRACT

An adhesive composition is provided. The adhesive composition includes an organic silicon polymer, a silicon coupling agent, carboxylic polyester, and a solvent. Based on the total weight of the adhesive composition, the content of the organic silicon polymer is 10 wt % to 60 wt %, the content of the silicon coupling agent is 10 wt % to 60 wt %, and the content of the carboxylic polyester is 10 wt % to 60 wt %.

### CROSS-REFERENCE TO RELATED APPLICATION

This application claims the priority benefit of Taiwan application serial no. 10600084, filed on Jan. 3, 2017. The entirety of the above-mentioned patent application is hereby incorporated by reference herein and made a part of this specification.

### BACKGROUND OF THE INVENTION

### Field of the Invention

The invention relates to a composition and a laminate including a film layer formed by the composition, and more particularly, to an adhesive composition and a flexible laminate including an adhesive layer formed by the adhesive composition.

### Description of Related Art

The flexible copper-clad laminate (FCCL) is the main upstream material for a flexible circuit board, and is generally formed by coating or attaching a polyimide polymer on copper foil. Currently, the development trend of the flexible electronic product is gradually heading toward wearable, attachable, and implantable product applications, and therefore the demand for extendability of the flexible copper-clad laminate is also increasing. However, the extendability of the flexible copper-clad laminate used in the current industry is poor, such that the application range thereof is limited.

### SUMMARY OF THE INVENTION

The invention provides an adhesive composition that can form an adhesive layer having good extendability and good adhesion with both metal and an elastic material.

The invention further provides a flexible laminate having good extendability and good adhesion between the film layers thereof.

An adhesive composition of the invention includes an organic silicon polymer, a silicon coupling agent, carboxylic polyester, and a solvent. Based on the total weight of the adhesive composition, the content of the organic silicon polymer is 10 wt % to 60 wt %, the content of the silicon coupling agent is 10 wt % to 60 wt %, and the content of the carboxylic polyester is 10 wt % to 60 wt %.

In an embodiment of the invention, the organic silicon polymer includes polysiloxane or polysilane.

In an embodiment of the invention, the carboxylic polyester is represented by formula 1 below:

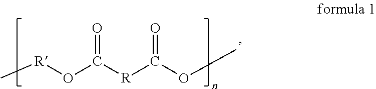

wherein R is a C₆ to C₁₂ straight-chain alkylene group or branched alkylene group containing at least one carboxylic acid group, R′ is a C₆ to C₁₂ straight-chain alkylene group or branched alkylene group, and n is 2 to 4.

In an embodiment of the invention, the weight-average molecular weight of the carboxylic polyester is 5000 to 15000.

In an embodiment of the invention, based on the total weight of the adhesive composition, the content of the organic silicon polymer is 20 wt % to 40 wt %, the content of the silicon coupling agent is 20 wt % to 40 wt %, and the content of the carboxylic polyester is 20 wt % to 40 wt %.

In an embodiment of the invention, the adhesive composition further includes an inorganic additive, wherein based on the total weight of the adhesive composition, the content of the inorganic additive is greater than 0 wt % to 20 wt %.

The flexible laminate of the invention includes an elastic layer, a first adhesive layer, and a first metal layer. The elastic layer has a first surface and a second surface opposite to each other. The first adhesive layer is disposed on the first surface of the elastic layer, wherein the first adhesive layer is formed by an adhesive composition, and the adhesive composition includes an organic silicon polymer, a silane coupling agent, carboxylic polyester, and a solvent. Based on the total weight of the adhesive composition, the content of the organic silicon polymer is 10 wt % to 60 wt %, the content of the silicon coupling agent is 10 wt % to 60 wt %, and the content of the carboxylic polyester is 10 wt % to 60 wt %. The first metal layer is disposed on the first surface of the elastic layer, wherein the first adhesive layer is located between the elastic layer and the first metal layer.

In an embodiment of the invention, the material of the elastic layer includes silicone, polyurethane (PU), or thermoplastic polyurethane (TPU).

In an embodiment of the invention, the organic silicon polymer includes polysiloxane or polysilane.

In an embodiment of the invention, the carboxylic polyester is represented by formula 1 below:

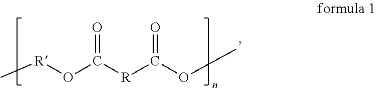

wherein R is a C₆ to C₁₂ straight-chain alkylene group or branched alkylene group containing at least one carboxylic acid group, R′ is a C₆ to C₁₂ straight-chain alkylene group or branched alkylene group, and n is 2 to 4.

In an embodiment of the invention, the weight-average molecular weight of the carboxylic polyester is 5000 to 15000.

In an embodiment of the invention, based on the total weight of the adhesive composition, the content of the organic silicon polymer is 20 wt % to 40 wt %, the content of the silicon coupling agent is 20 wt % to 40 wt %, and the content of the carboxylic polyester is 20 wt % to 40 wt %.

In an embodiment of the invention, the adhesive composition further includes an inorganic additive, wherein based on the total weight of the adhesive composition, the content of the inorganic additive is greater than 0 wt % to 20 wt %.

In an embodiment of the invention, the material of the first metal layer includes copper foil.

In an embodiment of the invention, the flexible laminate further includes a second adhesive layer disposed on the second surface of the elastic layer, wherein the second adhesive layer is forming by the adhesive composition above.

In an embodiment of the invention, the flexible laminate further includes a second metal layer disposed on the second surface of the elastic layer, wherein the second adhesive layer is located between the elastic layer and the second metal layer.

In an embodiment of the invention, the material of the second metal layer includes copper foil.

Based on the above, the adhesive composition of the invention includes an organic silicon polymer, a silicon coupling agent, carboxylic polyester, and a solvent, wherein the organic silicon polymer, the silicon coupling agent, and the carboxylic polyester have specific content ranges, and therefore the adhesive composition of the invention can form an adhesive layer having good extendability and good adhesion for both metal and an elastic material. Moreover, the flexible laminate of the invention includes an elastic layer, a metal layer, and an adhesive layer formed by the adhesive composition of the invention located between the elastic layer and the metal layer, and therefore the flexible laminate of the invention not only has good extendability, but the adhesion between the film layers in the flexible laminate of the invention is also good.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic diagram of a flexible laminate according to an embodiment of the invention.

FIG. 2 is a cross-sectional schematic diagram of a flexible laminate according to another embodiment of the invention.

### DESCRIPTION OF THE EMBODIMENTS

In the present specification, a range represented by “a numerical value to another numerical value” is a schematic representation for avoiding listing all of the numerical values in the range in the specification. Therefore, the recitation of a specific numerical range covers any numerical value in the numerical range and a smaller numerical range defined by any numerical value in the numerical range, as is the case with the any numerical value and the smaller numerical range stated explicitly in the specification.

In the present specification, wherever possible, the same reference numerals are used in the drawings and the descriptions to refer to the same or similar portions.

To provide a flexible copper-clad laminate having good extendability as the industry choice to meet the needs of some product applications, the invention provides an adhesive composition and a flexible laminate including an adhesive layer formed by the adhesive composition. In the following, embodiments are provided as examples of actual implementation of the invention.

An embodiment of the invention provides an adhesive composition. The adhesive composition includes an organic silicon polymer, a silicon coupling agent, carboxylic polyester, and a solvent. Hereinafter, the various components above are described in detail.

In the present embodiment, examples of the organic silicon polymer include (but are not limited to): polysiloxane or polysilane. Moreover, the organic silicon polymer can also adopt a commercial product such as SEBA-350-6 (made by Green & UL Foam Technology Ltd.). In the present embodiment, based on the total weight of the adhesive composition, the content of the organic silicon polymer is 10 wt % to 60 wt %, preferably 20 wt % to 40 wt %. Specifically, if the content of the organic silicon polymer is less than 10 wt %, or if the content of the organic silicon polymer is higher than 60 wt %, then the issue of insufficient mechanical strength occurs to the adhesive layer formed by the adhesive composition.

In the present embodiment, the silicon coupling agent can be any silicon coupling agent known to any person having ordinary skill in the art. Specifically, examples of the silicon coupling agent include (but are not limited to): a silicon compound containing an epoxy group such as 3-glycidoxypropyltrimethoxysilane, 3-glycidoxypropylmethyldimethoxysilane, or 2-(3,4-epoxycyclohexyl)ethyltrimethoxysilane; a silicon compound containing a polymerizable unsaturated group such as vinyltrimethoxysilane, vinyltriethoxysilane, or (meth)acryloxypropyltrimethoxysilane; a silicon compound containing an amino group such as 3-aminopropyltrimethoxysilane, N-(2-aminoethyl)-3-aminopropyltrimethoxysilane, or N-(2-aminoethyl)-3-aminopropylmethyldimethoxysilane; or 3-chloropropyltrimethoxysilane. Moreover, the silicon coupling agent can also adopt a commercial product such as Primer-A4E (made by Green & UL Foam Technology Ltd.). In the present embodiment, based on the total weight of the adhesive composition, the content of the silicon coupling agent is 10 wt % to 60 wt %, preferably 20 wt % to 40 wt %. Specifically, if the content of the silicon coupling agent is less than 10 wt %, or if the content of the silicon coupling agent is higher than 60 wt %, then the issue of insufficient peel strength occurs to the adhesive layer formed by the adhesive composition.

It should be mentioned that, in the present embodiment, the adhesive composition includes the organic silicon polymer and the silicon coupling agent, such that the adhesive layer formed by the adhesive composition can have adhesion for an elastic material (such as: silicone, polyurethane (PU), or thermoplastic polyurethane (TPU)).

In the present embodiment, the carboxylic polyester can be any carboxylic polyester known to those having ordinary skill in the art. Specifically, in an embodiment, the carboxylic polyester can be represented by formula 1 below:

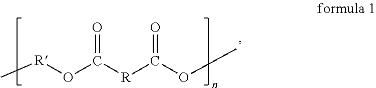

wherein R is a C₆ to C₁₂ straight-chain alkylene group or branched alkylene group containing at least one carboxylic acid group, R′ is a C₆ to C₁₂ straight-chain alkylene group or branched alkylene group, and n is 2 to 4. Specifically, in formula 1, R can be substituted by a substituent other than a carboxylic acid group or not substituted by a substituent other than a carboxylic acid group. Moreover, in the present embodiment, the weight-average molecular weight of the carboxylic polyester is 5000 to 15000, preferably 5000 to 10000. Specifically, if the weight-average molecular weight of the carboxylic polyester is less than 5000, or if the weight-average molecular weight of the carboxylic polyester is higher than 15000, then the issue of insufficient mechanical strength occurs to the adhesive layer formed by the adhesive composition. Moreover, in the present embodiment, based on the total weight of the adhesive composition, the content of the carboxylic polyester is 10% to 60 wt %, preferably 20 wt % to 40 wt %. Specifically, if the content of the carboxylic polyester is less than 10 wt %, or if the content of the carboxylic polyester is higher than 60 wt %, then the issue of insufficient peel strength occurs to the adhesive layer formed by the adhesive composition.

It should be mentioned that, in the present embodiment, the adhesive composition includes the carboxylic polyester, and therefore the adhesive layer formed by the adhesive composition has adhesion for metal.

Moreover, the adhesive composition can further include an inorganic additive as needed. Specifically, the inorganic additive is, for instance, an inorganic filler, and examples thereof include (but are not limited to): aluminum hydroxide, crystalline silicon dioxide, amorphous silicon dioxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, or a combination thereof. Moreover, in the present embodiment, based on the total weight of the adhesive composition, the content of the inorganic additive is greater than 0 wt % to 20 wt %, preferably 5 wt % to 20 wt %. Specifically, if the content of the inorganic additive is greater than 20 wt %, then the adhesive layer formed by the adhesive composition has the issue of insufficient mechanical strength.

In the present embodiment, the type of the solvent is not particularly limited as long as the organic silicon polymer, silicon coupling agent, carboxylic polyester, and inorganic additive can be dissolved. Specifically, examples of the solvent include (but are not limited to) an alcohol solvent such as: methanol, ethanol, isopropanol, or a combination thereof.

It should be mentioned that, in the present embodiment, by including the organic silicon polymer, the silicon coupling agent, and the carboxylic polyester having contents in a specific range (i.e., 10 wt % to 60 wt %), the adhesive composition can form an adhesive layer having good extendability and good adhesion for both metal and an elastic material. Moreover, in the present embodiment, by including the organic silicon polymer, the silicon coupling agent, and the carboxylic polyester having contents in a specific range (i.e., 10 wt % to 60 wt %), the adhesive layer formed by the adhesive composition also has good heat resistance. In an embodiment, the heat resistance of the adhesive layer formed by the adhesive composition reaches 350° C.

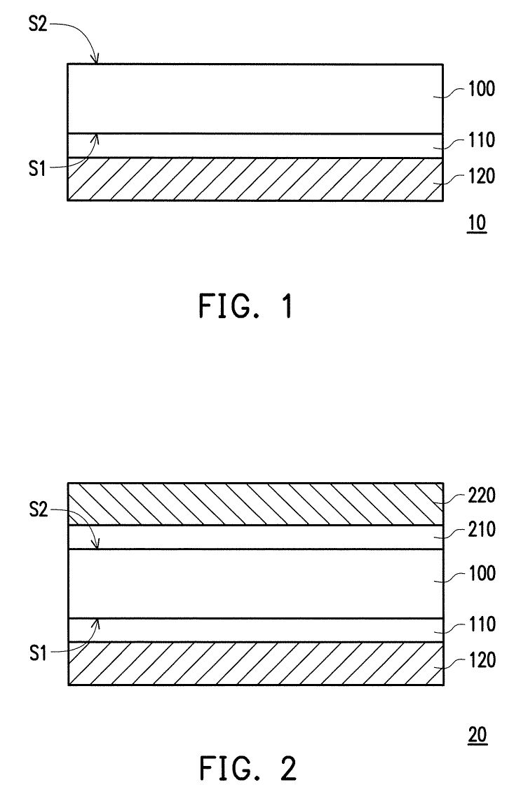

More specifically, since the adhesive composition has the advantages above, the adhesive composition can be applied in a laminate including a metal layer and an elastic layer. In the following, embodiments of FIG. 1 and FIG. 2 are described in detail as examples of actual implementation of the invention.

FIG. 1 is a cross-sectional schematic diagram of a flexible laminate according to an embodiment of the invention. Referring to FIG. 1, a flexible laminate 10 includes an elastic layer 100, a first adhesive layer 110, and a first metal layer 120. In other words, the flexible laminate 10 is a three-layer stacked structure.

In the present embodiment, the elastic layer 100 has a first surface S1 and a second surface S2 opposite to each other. Specifically, the elastic layer 100 itself has good extendability, and the material thereof includes (but is not limited to): silicone, polyurethane, or thermoplastic polyurethane. It should be mentioned that, out of consideration of heat resistance, the material of the elastic layer 100 preferably includes silicone having heat resistance reaching 350° C. Moreover, the thickness of the elastic layer 100 is not particularly limited, and can be adjusted based on the elastic requirements of the application for the flexible laminate 10. In an embodiment, the thickness of the elastic layer 100 is about 50 μm to 300 μm. In an embodiment, when the thickness of the elastic layer 100 is about 300 μm, the extension ratio of the elastic layer 100 can reach 200% or more. In an embodiment, when the thickness of the elastic layer 100 is about 50 μm, the extension ratio of the elastic layer 100 is 90%.

In the present embodiment, the first adhesive layer 110 is disposed on the first surface S1 of the elastic layer 100. Specifically, the first adhesive layer 110 is formed by the adhesive composition of any of the embodiments above, wherein relevant descriptions of the adhesive composition and the components thereof are described in detail in the above embodiments and are therefore not repeated herein.

In the present embodiment, the first metal layer 120 is disposed on the first surface S1 of the elastic layer 100, and the first adhesive layer 110 is located between the elastic layer 100 and the first metal layer 120. Specifically, the first adhesive layer 110 is formed by the adhesive composition of any of the embodiments above, and therefore the main function of the first adhesive layer 110 is the direct adhesion of the elastic layer 100 and the first metal layer 120, and the adhesion between the first adhesive layer 110 and the elastic layer 100 and between the first adhesive layer 110 and the first metal layer 120 is good. Accordingly, in the present embodiment, the thickness of the first adhesive layer 110 is not particularly limited as long as the elastic layer 100 and the first metal layer 120 can be adhered. In an embodiment, the thickness of the first adhesive layer 110 is about 1 μm to 3 μm.

Moreover, in the present embodiment, the material of the first metal layer 120 includes (but is not limited to): copper foil such as rolled copper foil, electrolytic copper foil, or aluminum foil. It should be mentioned that, in an embodiment in which the material of the first metal layer 120 is copper foil, the flexible laminate 10 can be used as a flexible copper-clad laminate, wherein the elastic layer 100 is used as a single panel flexible substrate in the flexible copper-clad laminate.

It should be mentioned that, in the present embodiment, since the flexible laminate 10 includes the elastic layer 100, the first adhesive layer 110 formed by the adhesive composition of any of the embodiments above, and the first metal layer 120, the flexible laminate 10 has good extendability. More specifically, when the material of the first metal layer 120 is copper foil, in comparison to a known flexible copper-clad laminate including a polyimide film, the flexible laminate 10 of the invention can still maintain good extendability.

Moreover, since the first adhesive layer 110 formed by the adhesive composition of any of the embodiments above is located between the elastic layer 100 and the first metal layer 120, the adhesion between the film layers in the flexible laminate 10 is good, such that the process yield and applicability of the flexible laminate 10 are increased.

Moreover, since the flexible laminate 10 includes the elastic layer 100, the first adhesive layer 110 formed by the adhesive composition of any of the embodiments above, and the first metal layer 120, the flexible laminate 10 has good flexibility.

Moreover, since the flexible laminate 10 includes the elastic layer 100, the first adhesive layer 110 formed by the adhesive composition of any of the embodiments above, and the first metal layer 120, the flexible laminate 10 can be made by a coating process. In an embodiment, the manufacturing method of the flexible laminate 10 includes, for instance, the following steps. First, after the adhesive composition of any of the embodiments above is coated on the first metal layer 120 by a coating process, the first adhesive layer 110 is formed by performing a curing process. Next, after an elastic material solution is coated on the first adhesive layer 110 by a coating process, a baking process is performed to form the elastic layer 100. In the above steps, the coating process can be any coating process known to any person having ordinary skill in the art, such as roll coating, blade coating, slide coating, slot-die coating, or wire bar coating; the curing temperature is, for instance, between 140° C. and 180° C.; the curing time is, for instance, between 1 minute and 5 minutes; the baking temperature is, for instance, between 140° C. and 180° C.; and the baking time is, for instance, between 15 minutes and 30 minutes. As a result, during the manufacturing process of the flexible laminate 10, since the elastic layer 100 and the first adhesive layer 110 are formed by a coating process, the thicknesses of the elastic layer 100 and the first adhesive layer 110 can be effectively controlled.

FIG. 2 is a cross-sectional schematic diagram of a flexible laminate according to another embodiment of the invention. It should be mentioned here that, the embodiment of FIG. 2 adopts the reference numerals of the embodiment of FIG. 1 and a portion of the content thereof, wherein the same or similar reference numerals are used to represent the same or similar components and descriptions of the same technical content are omitted. The omitted portions are described in the previous embodiments and are not repeated in the following embodiments.

Referring to both FIG. 2 and FIG. 1, a flexible laminate 20 of the present embodiment is similar to the flexible laminate 10 of FIG. 1, and the main difference is: the flexible laminate 20 further includes a second adhesive layer 210 and a second metal layer 220. In the following, the differences between the two embodiments are described.

Referring to FIG. 2, the second adhesive layer 210 is disposed on the second surface S2 of the elastic layer 100. In other words, the elastic layer 100 is located between the second adhesive layer 210 and the first adhesive layer 110. Moreover, in the present embodiment, the second adhesive layer 210 is formed by the adhesive composition of any of the embodiments above, wherein relevant descriptions of the adhesive composition and the components thereof are described in detail in the above embodiments and are therefore not repeated herein. Moreover, the adhesive composition forming the second adhesive layer 210 can be the same as or different from the adhesive composition forming the first adhesive layer 110.

In the present embodiment, the second metal layer 220 is disposed on the second surface S2 of the elastic layer 100, and the second adhesive layer 210 is located between the elastic layer 100 and the second metal layer 220. Specifically, the second adhesive layer 210 is formed by the adhesive composition of any of the embodiments above, and therefore the main function of the first adhesive layer 210 is the direct adhesion of the elastic layer 100 and the second metal layer 220, and the adhesion between the second adhesive layer 210 and the elastic layer 100 and between the second adhesive layer 210 and the second metal layer 220 is good. Accordingly, in the present embodiment, the thickness of the second adhesive layer 210 is not particularly limited as long as the elastic layer 100 and the second metal layer 220 can be adhered. In an embodiment, the thickness of the second adhesive layer 210 is about 1 μm to 3 μm.

Moreover, in the present embodiment, the material of the second metal layer 220 includes (but is not limited to): copper foil such as rolled copper foil, electrolytic copper foil, or aluminum foil. It should be mentioned that, in the embodiment in which the materials of the first metal layer 120 and the second metal layer 220 are both copper foil, the flexible laminate 20 can be used as a flexible copper-clad laminate, wherein the elastic layer 100 is used as a double-sided panel flexible substrate in the flexible copper-clad laminate.

It should be mentioned that, in the present embodiment, since the flexible laminate 20 includes the elastic layer 100, the first adhesive layer 110 formed by the adhesive composition of any of the embodiments above, the first metal layer 120, the second adhesive layer 210 formed by the adhesive composition of any of the embodiments above, and the second metal layer 220, the flexible laminate 20 has good extendability. More specifically, when the materials of the first metal layer 120 and the second metal layer 220 are both copper foil, in comparison to a known flexible copper-clad laminate including a polyimide film, the flexible laminate 20 of the invention can still maintain good extendability.

Moreover, since the first adhesive layer 110 formed by the adhesive composition of any of the embodiments above is located between the elastic layer 100 and the first metal layer 120 and the second adhesive layer 210 formed by the adhesive composition of any of the embodiments above is located between the elastic layer 100 and the second metal layer 220, the adhesion between the film layers in the flexible laminate 20 is good, such that the process yield and applicability of the flexible laminate 20 are increased.

Moreover, since the flexible laminate 20 includes the elastic layer 100, the first adhesive layer 110 formed by the adhesive composition of any of the embodiments above, the first metal layer 120, the second adhesive layer 210 formed by the adhesive composition of any of the embodiments above, and the second metal layer 220, the flexible laminate 20 has good flexibility.

Moreover, since the flexible laminate 20 includes the elastic layer 100, the first adhesive layer 110 formed by the adhesive composition of any of the embodiments above, the first metal layer 120, the second adhesive layer 210 formed by the adhesive composition of any of the embodiments above, and the second metal layer 220, the flexible laminate 20 can be made by a coating process. In an embodiment, the manufacturing method of the flexible laminate 20 includes, for instance, the following steps. First, after the adhesive composition of any of the embodiments above is coated on the first metal layer 120 by a coating process, the first adhesive layer 110 is formed by performing a curing process. Next, after an elastic material solution is coated on the first adhesive layer 110 by a coating process, a baking process is performed to form the elastic layer 100. Moreover, after the adhesive composition of any of the embodiments above is similarly coated on the second metal layer 220 by a coating process, the second adhesive layer 210 is formed by performing a curing process. Lastly, the second adhesive layer 210 formed on the second metal layer 220 is pressed on the elastic layer 100 at room temperature. In the above steps, the coating process can be any coating process known to any person having ordinary skill in the art, such as roll coating, blade coating, slide coating, slot-die coating, or wire bar coating; the curing temperature is, for instance, between 140° C. and 180° C.; the curing time is, for instance, between 1 minute and 5 minutes; the baking temperature is, for instance, between 140° C. and 180° C.; and the baking time is, for instance, between 15 minutes and 30 minutes. As a result, during the manufacturing process of the flexible laminate 20, since the elastic layer 100, the first adhesive layer 110, and the second adhesive layer 210 are formed by a coating process, the thicknesses of the elastic layer 100, the first adhesive layer 110, and the second adhesive layer 210 can be effectively controlled.

The features of the invention are more specifically described in the following with reference to Examples 1 to 4 and Comparative Example 1. Although the following Examples 1 to 4 are described, the materials used and the amounts and ratios thereof, as well as handling details and handling processes . . . etc. can be suitably modified without exceeding the scope of the invention. Accordingly, restrictive interpretation should not be made to the invention based on the examples described below.

### Example 1

### Preparation of Adhesive Composition

Under room temperature, 40 wt % of an organic silicon polymer (product name: SEBA-350-6, purchased from Green & UL Foam Technology Ltd.), 20 wt % of a silicon coupling agent (product name: Primer-A4E, purchased from Green & UL Foam Technology Ltd.), and 40 wt % of carboxylic acid polyester (weight-average molecular weight: 10000, purchased from Howren Trading Co., Ltd.) were dissolved and dispersed in 30 mL of an isopropanol solvent to form the adhesive composition of example 1.

### Manufacture of Flexible Laminate

First, after the adhesive composition of Example 1 was coated on rolled copper foil having a thickness of 18 μm using a roll coating machine, a curing process was performed for 1 minute at a temperature of 140° C. to form an adhesive layer having a thickness of 3 μm on the rolled copper foil. Next, silicone (product name: SEBA-350-6, purchased from Green & UL Foam Technology Ltd.) was dissolved and dispersed in a butanone solvent to form a silicone solution. Next, after the silicone solution was coated on the adhesive layer using a roll coating machine, a baking process was performed for 1 minute at a temperature of 150° C. to form a silicone layer (i.e., elastic layer) having a thickness of 300 μm on the adhesive layer to complete the manufacture of the flexible laminate of Example 1.

### Example 2

### Preparation of Adhesive Composition

Under room temperature, 30 wt % of an organic silicon polymer (product name: SEBA-350-6, purchased from Green & UL Foam Technology Ltd.), 30 wt % of a silicon coupling agent (product name: Prime A4E, purchased from Green & UL Foam Technology Ltd.), 30 wt % of carboxylic acid polyester (weight-average molecular weight: 10000, purchased from Howren), and 10 wt % of aluminum hydroxide (i.e., inorganic additive) were dissolved and dispersed in 30 mL of an isopropanol solvent to form the adhesive composition of Example 2.

### Manufacture of Flexible Laminate

First, after the adhesive composition of Example 2 was coated on rolled copper foil having a thickness of 18 μm using a roll coating machine, a curing process was performed for 1 minute at a temperature of 140° C. to form an adhesive layer having a thickness of 3 μm on the rolled copper foil. Next, silicone (product name: SEBA-350-6, purchased from Green & UL Foam Technology Ltd.) was dissolved and dispersed in a butanone solvent to form a silicone solution. Next, after the silicone solution was coated on the adhesive layer using a roll coating machine, a baking process was performed for 1 minute at a temperature of 150° C. to form a silicone layer (i.e., elastic layer) having a thickness of 300 μm on the adhesive layer to complete the manufacture of the flexible laminate of Example 2.

### Example 3

### Preparation of Adhesive Composition

The adhesive composition of Example 3 was prepared based on the same preparation process as Example 2.

### Manufacture of Flexible Laminate

First, after the adhesive composition of Example 3 was coated on rolled copper foil having a thickness of 70 μm using a roll coating machine, a curing process was performed for 1 minute at a temperature of 140° C. to form an adhesive layer having a thickness of 3 μm on the rolled copper foil. Next, silicone (product name: SEBA-350-6, purchased from Green & UL Foam Technology Ltd.) was dissolved and dispersed in a butanone solvent to form a silicone solution. Next, after the silicone solution was coated on the adhesive layer using a roll coating machine, a baking process was performed for 1 minute at a temperature of 150° C. to form a silicone layer (i.e., elastic layer) having a thickness of 50 μm on the adhesive layer to complete the manufacture of the flexible laminate of example 3.

### Example 4

### Preparation of Adhesive Composition

The adhesive composition of Example 4 was prepared based on the same preparation process as Example 2.

### Manufacture of Flexible Laminate

First, after the adhesive composition of Example 4 was coated on rolled copper foil having a thickness of 9 μm using a roll coating machine, a curing process was performed for 1 minute at a temperature of 140° C. to form an adhesive layer having a thickness of 3 μm on the rolled copper foil. Next, silicone (product name: SEBA-350-6, purchased from Green & UL Foam Technology Ltd.) was dissolved and dispersed in a butanone solvent to form a silicone solution. Next, after the silicone solution was coated on the adhesive layer using a roll coating machine, a baking process was performed for 1 minute at a temperature of 150° C. to form a silicone layer (i.e., elastic layer) having a thickness of 300 μm on the adhesive layer to complete the manufacture of the flexible laminate of Example 4.

### Comparative Example 1

### Manufacture of Flexible Laminate

First, silicone (product name: SEBA-350-6, purchased from Green & UL Foam Technology Ltd.) was dissolved and dispersed in a butanone solvent to form a silicone solution. Next, after the silicone solution was coated on a rolled copper foil having a thickness of 18 μm using a roll coating machine, a baking process was performed for 1 minute at a temperature of 150° C. to form a silicone layer (i.e., elastic layer) having a thickness of 300 μm on the copper foil to complete the manufacture of the flexible laminate of Comparative Example 1.

Next, measurements of extension ratio and peel strength were respectively performed on the flexible laminates of Examples 1 to 4 and the flexible laminate of Comparative Example 1. The above measurements are as described below, and the measurement results are shown in Table 1.

### <Measurement of Extension Ratio>

Measurements of extension ratio were respectively performed on the flexible laminates of Examples 1 to 4 and the flexible laminate of Comparative Example 1 according to the provisions of ASTM D412. A higher extension ratio represents better extendability.

### <Measurement of Peel Strength>

Measurements of peel strength were respectively performed on the flexible laminates of Examples 1 to 4 and the flexible laminate of Comparative Example 1 according to the provisions of IPC TM 650 2.4.9. A greater peel strength represents better adhesion between the film layers. In the industry, in applications of a flexible copper-clad laminate, the peel strength between the film layers needs to be at least 0.5 kgf/cm.

TABLE 1

| | | | | | Comparative |
|---|---|---|---|---|---|
| | Example 1 | Example 2 | Example 3 | Example 4 | Example 1 |
| Extension | 200 | 200 | 90 | 390 | 200 |
| ratio (%) | | | | | |
| Peel | ≥1.0 | ≥1.0 | ≥1.0 | ≥1.0 | 0.1 |
| strength | | | | | |
| (kgf/cm) | | | | | |

It can be known from Table 1 that, the extension ratios of the flexible laminates of Examples 1 to 2 for which the silicone layer and the rolled copper foil have the same thickness and the flexible laminate of Comparative Example 1 are similar. Accordingly, the flexible laminate of the invention includes a metal layer, an adhesive layer, and an elastic layer, wherein the adhesive layer is located between the metal layer and the elastic layer, and the adhesive layer is formed by an adhesive composition including an organic silicon polymer, a silicon coupling agent, and carboxylic polyester having contents in a specific range, and therefore in comparison to a flexible laminate without the adhesive layer, the flexible laminate of the invention can still maintain good extendability.

Moreover, it can be known from Table 1 that, the peel strength of the flexible laminates of Examples 1 to 4 is good. In comparison to the flexible laminates of Examples 1 to 4 including a metal layer, an adhesive layer, and an elastic layer, although the flexible laminate of Comparative Example 1 without the adhesive layer has good extendability, the peel strength thereof is only 0.1 kgf/cm, and therefore issues such as peeling, foaming, and warping of film layers readily occur, such that the flexible laminate of Comparative Example 1 is not suitable for application in a flexible copper-clad laminate. Accordingly, the flexible laminate of the invention includes a metal layer, an adhesive layer, and an elastic layer, wherein the adhesive layer is located between the metal layer and the elastic layer, and the adhesive layer is formed by an adhesive composition including an organic silicon polymer, a silicon coupling agent, and carboxylic polyester having contents in a specific range, and therefore in comparison to a flexible laminate without the adhesive layer, not only does the flexible laminate of the invention still has good extendability, the adhesion between the film layers thereof is also effectively increased.

Based on the above, the adhesive composition of the invention includes an organic silicon polymer, a silicon coupling agent, carboxylic polyester, and a solvent, wherein based on the total weight of the adhesive composition, the contents of the organic silicon polymer, the silicon coupling agent, and the carboxylic polyester are all 10 wt % to 60 wt %, and therefore the adhesive composition of the invention can form an adhesive layer having good extendability and good adhesion for both metal and an elastic material. Moreover, the flexible laminate of the invention includes an elastic layer, a metal layer, and an adhesive layer formed by the adhesive composition of the invention located between the elastic layer and the metal layer, and therefore the flexible laminate of the invention not only has good extendability, but the adhesion between the film layers in the flexible laminate of the invention is also increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An adhesive composition, comprising:
an organic silicon polymer;
a silicon coupling agent;
a carboxylic polyester; and
a solvent, wherein based on a total weight of the adhesive composition, a content of the organic silicon polymer is 10 wt % to 60 wt %, a content of the silicon coupling agent is 10 wt % to 60 wt %, and a content of the carboxylic polyester is 10 wt % to 60 wt %.

2. The adhesive composition of claim 1, wherein the organic silicon polymer comprises polysiloxane or polysilane.

3. The adhesive composition of claim 1, wherein the carboxylic polyester is represented by formula 1 below: 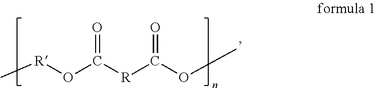
wherein R is a C₆ to C₁₂ straight-chain alkylene group or branched alkylene group containing at least one carboxylic acid group, R′ is a C₆ to C₁₂ straight-chain alkylene group or branched alkylene group, and n is 2 to 4.

4. The adhesive composition of claim 1, wherein a weight-average molecular weight of the carboxylic polyester is 5000 to 15000.

5. The adhesive composition of claim 1, wherein based on the total weight of the adhesive composition, the content of the organic silicon polymer is 20 wt % to 40 wt %, the content of the silicon coupling agent is 20 wt % to 40 wt %, and the content of the carboxylic polyester is 20 wt % to 40 wt %.

6. The adhesive composition of claim 1, further comprising an inorganic additive, wherein based on the total weight of the adhesive composition, a content of the inorganic additive is greater than 0 wt % to 20 wt %.

7. A flexible laminate, comprising:
an elastic layer having a first surface and a second surface opposite to each other;
a first adhesive layer disposed on the first surface of the elastic layer, wherein the first adhesive layer is formed by an adhesive composition, and the adhesive composition comprises:
an organic silicon polymer;
a silicon coupling agent;
a carboxylic polyester; and
a solvent, wherein based on a total weight of the adhesive composition, a content of the organic silicon polymer is 10 wt % to 60 wt %, a content of the silicon coupling agent is 10 wt % to 60 wt %, and a content of the carboxylic polyester is 10 wt % to 60 wt %; and
a first metal layer disposed on the first surface of the elastic layer, wherein the first adhesive layer is located between the elastic layer and the first metal layer.

8. The flexible laminate of claim 7, wherein a material of the elastic layer comprises silicone, polyurethane (PU), or thermoplastic polyurethane (TPU).

9. The flexible laminate of claim 7, wherein the organic silicon polymer comprises polysiloxane or polysilane.

10. The flexible laminate of claim 7, wherein the carboxylic polyester is represented by formula 1 below: 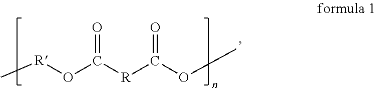
wherein R is a C₆ to C₁₂ straight-chain alkylene group or branched alkylene group containing at least one carboxylic acid group, R′ is a C₆ to C₁₂ straight-chain alkylene group or branched alkylene group, and n is 2 to 4.

11. The flexible laminate of claim 7, wherein a weight-average molecular weight of the carboxylic polyester is 5000 to 15000.

12. The flexible laminate of claim 7, wherein based on the total weight of the adhesive composition, the content of the organic silicon polymer is 20 wt % to 40 wt %, the content of the silicon coupling agent is 20 wt % to 40 wt %, and the content of the carboxylic polyester is 20 wt % to 40 wt %.

13. The flexible laminate of claim 7, wherein the adhesive composition further comprises an inorganic additive, and based on the total weight of the adhesive composition, a content of the inorganic additive is greater than 0 wt % to 20 wt %.

14. The flexible laminate of claim 7, wherein a material of the first metal layer comprises copper foil.

15. The flexible laminate of claim 7, further comprising a second adhesive layer disposed on the second surface of the elastic layer, wherein the second adhesive layer is formed by the adhesive composition.

16. The flexible laminate of claim 15, further comprising a second metal layer disposed on the second surface of the elastic layer, wherein the second adhesive layer is located between the elastic layer and the second metal layer.

17. The flexible laminate of claim 16, wherein a material of the second metal layer comprises copper foil.
